(19) United States
(12) Patent Application Publication
(10) Pub. No.: US 2017/0255808 A1
(43) Pub. Date: Sep. 7, 2017

(54) FINGERPRINT RECOGNIZING SENSOR WITH FAST RECOGNITION

(71) Applicant: APEX MICROELECTRONICS CO., LTD., Zhuhai (CN)

(72) Inventor: Jungkuo HSU, Zhubei (TW)

(73) Assignee: APEX MICROELECTRONICS CO., LTD., Zhuhai (CN)

(21) Appl. No.: 15/602,052

(22) Filed: May 22, 2017

Related U.S. Application Data
(63) Continuation of application No. PCT/IB2016/053913, filed on Jun. 30, 2016.

(30) Foreign Application Priority Data
Aug. 3, 2015 (TW) 104125062

(51) Int. Cl. G06K 9/00; G06F 3/044

(52) U.S. Cl. CPC G06K 9/0002; G06K 9/00033; G06F 3/044; H03M 1/001

(57) ABSTRACT

A fingerprint recognizing sensor with fast recognition, including: a substrate, a conductive plate, a passivation layer, a charging capacitor, a switch group, and an analog to digital (AD) converter; the conductive plate being arranged on the substrate; the passivation layer being arranged on the conductive pad for receiving a finger to detect a fingerprint; the switch group including a first switch and a second switch; the first switch controlling an input voltage to charge the charging capacitor; two ends of the second switch being electrically connected to the conductive plate and the first switch as well as the charging capacitor, respectively; the AD converter being electrically connected to the charging capacitor; where the second switch controls the charging capacitor to perform charge sharing for multiple times; and the AD converter outputs a fingerprint recognizing signal according to a residual voltage after the charge sharing.

### TECHNICAL FIELD

The invention relates to a fingerprint recognizing sensor, and particularly, to a fingerprint recognizing sensor with fast recognition.

### BACKGROUND

With emerging awareness over personal information protection and privacy rights, methods for identifying individual identities are evolving. Compared with traditional methods, e.g. signature recognition and password recognition, which suffer from vulnerability to forgery or fraudulent use, bio-feature based applications that emphasize individual uniqueness and differences are entering into the field of identity recognition recently. Among bio-feature based recognizing methods, e.g. facial contour recognition, iris recognition and fingerprint recognition, the fingerprint recognition enjoys advantages with respect to ease-of-use, individual differentiation and industrial applications, and has undergone blooming development and wide applications in many industries.

Fingerprint recognition has been widely applied in many industrial fields. For instance, Chinese Patent Publication No. CN102954753A discloses a capacitive distance sensor that includes a capacitance measuring plate, a capacitive coupling plate, a reference capacitor, a reference capacitor charging circuit, a capacitance measuring plate discharging circuit, a charge neutralizing circuit, a programmable designed level generator, a programmable designed level generator 2, and a voltage comparator, where the capacitance measuring plate is connected to the charge neutralizing circuit, and a measuring capacitor is formed between the capacitance measuring plate and a surface of the conductive body being measured when the surface of the conductive body being measured is brought into close proximity to an upper surface of the capacitance measuring plate; the capacitive coupling plate is connected to the programmable designed level generator, and is located beneath the capacitance measuring plate, and a coupling capacitor is formed between the capacitive coupling plate and the capacitance measuring plate; one end of the reference capacitor is connected to the reference capacitor charging circuit, the charge neutralizing circuit and an input of the voltage comparator; the reference capacitor charging circuit is connected, at one end, to the reference capacitor, and at the other end, to a system power source, the closed state thereof allows the reference capacitor to be electrically connected to the system power source, and the opened state isolates the reference capacitor from the system power source; the capacitance measuring plate discharging circuit is connected, at one end, to the capacitance measuring plate, the closed state thereof allows the capacitance measuring plate to be electrically connected to a system ground, and the opened state isolates the capacitance measuring plate from the system ground; the charge neutralizing circuit is connected, at one end, to the reference capacitor, and at the other end, to the capacitance measuring plate, the closed state thereof allows the reference capacitor to be electrically connected to the capacitance measuring plate, and the opened state isolates the reference capacitor from the capacitance measuring plate; the programmable designed level generator is connected to the capacitive coupling plate; and the input of the voltage comparator is connected to the reference capacitor and the programmable designed level generator 2, and the output thereof serves as the sensor output.

The above described prior art is also referred to as a C-V-T type capacitance sensor circuit. In practical use, the reference capacitor charging circuit needs to be repeatedly switched between the closed state and the opened state; when accumulated signals exceed the programmable designed level generator 2, the voltage comparator begins outputting signals. However, this type of capacitance sensor circuit adopts the programmable designed level generator 2, i.e. a comparator, and the acquired signal of the comparator is the number of times of the reference capacitor charging circuit being closed and opened, which hence needs longer recognition time. Moreover, when there are multiple pixels (sensors), these multiple pixels may be connected to a common comparator, or each pixel may be connected to one comparator, respectively. Yet, considering the volume and manufacturing cost, the latter is infeasible, and hence in practice, multiple pixels are usually connected to a common comparator. However, this arrangement is disadvantageous in that, individual pixels have to undergo the judgment of the comparator sequentially before a signal is acquired, which is highly time consuming.

### SUMMARY

The present invention mainly aims at solving the problem that an existing C-V-T type capacitance sensor circuit takes extensive time to recognize a fingerprint.

For achieving the above objective, the invention provides a fingerprint recognizing sensor with fast recognition, which includes: a substrate; a conductive plate arranged on the substrate; a passivation layer arranged on the conductive plate for receiving a finger to detect a fingerprint; a charging capacitor, including a discharging end electrically connected to a low level voltage, and a charging end electrically connected to the conductive plate; a switch group, including a first switch and a second switch, tow ends of the first switch being electrically connected to an input voltage and the charging end of the charging capacitor, respectively, and located between the input voltage and the charging end of the charging capacitor, to control the input voltage to charge the charging capacitor; two ends of the second switch being electrically connected to the conductive plate and the first switch as well as the charging end of the charging capacitor, respectively; the input voltage being higher than the low level voltage; and an analog to digital (AD) converter electrically connected to the charging end of the charging capacitor; wherein after the first switch controls the charging capacitor to perform charging for a single time, the second switch controls the charging capacitor to perform charge sharing for multiple times, and the AD converter outputs a fingerprint recognizing signal according to a residual voltage at the charging end after the charge sharing.

For achieving the above objective, the invention further provides a fingerprint recognizing sensor with fast recognition, which includes: a substrate; a plurality of fingerprint recognition sensing units arranged on the substrate, each of the fingerprint recognition sensing units including: a conductive plate arranged on the substrate; a passivation layer arranged on the conductive plate for receiving a finger to detect a fingerprint; a charging capacitor, including a discharging end electrically connected to a low level voltage, and a charging end electrically connected to the conductive plate; and a switch group, including a first switch and a second switch, two ends of the first switch being electrically connected to an input voltage and the charging end of the charging capacitor, respectively, and located between the input voltage and the charging end of the charging capacitor, to control the input voltage to charge the charging capacitor; two ends of the second switch being electrically connected to the conductive plate and the first switch as well as the charging end of the charging capacitor, respectively; the input voltage being higher than the low level voltage; and an analog to digital (AD) converter electrically connected to the charging end of the charging capacitor in each of the fingerprint recognition sensing units; wherein after the first switch in each of the fingerprint recognition sensing units controls the charging capacitor to perform charging for a single time, the second switch controls the charging capacitor to perform charge sharing for multiple times, and the AD converter outputs a fingerprint recognizing signal according to a residual voltage at the charging end after the charge sharing.

The invention adopts the AD converter to output the fingerprint recognizing signal according to the residual voltage at the charging end after the charge sharing, where the input to, and output from, the AD converter are actual voltage values, which can be accomplished rapidly. When multiple pixels (i.e. the fingerprint recognition sensing units) are arranged, the fingerprint recognition sensing units of the invention can simultaneously perform charge sharing, accumulate the residual voltage at the charging end and then make the same go through the AD converter sequentially, which can be accomplished very rapidly as well; instead, in a traditional C-V-T type capacitance sensor circuit, every pixel (i.e. the fingerprint recognition sensing unit) has to work with a common comparator, and each pixel has to wait for its previous pixel before the each pixel begins performing the switching operation, because simultaneous switching for the pixels are not allowed, thus the time for acquisition is slow. In addition, the output from the AD converter is an actual voltage value, which is convenient for subsequent signal processing; however, in the traditional C-V-T type capacitance sensor circuit, the output from the comparator is a value corresponding to the number of times of the switching operation. Moreover, for the static fingerprint image acquisition, the residual voltage is the accumulation of signals after charge sharing for multiple times. The residual voltage will be accumulated successively, while the noise will not be accumulated accordingly, thus helping to improve the signal-to-noise ratio (SNR).

### BRIEF DESCRIPTION OF DRAWINGS

FIG. 1 is a schematic circuit diagram according to a first embodiment of the present invention;

FIG. 2 is an equivalent circuit diagram of FIG. 1;

FIG. 3 is a control timing diagram according to the first embodiment of the present invention; and

FIG. 4 is a schematic circuit diagram according to a second embodiment of the present invention.

### DESCRIPTION OF REFERENCE SIGNS

10: substrate

20: conductive plate

30: passivation layer

40: AD converter

50: finger

60: amplifier

70: fingerprint recognition sensing unit

C₀: charging capacitor

Cₛ: detecting capacitor

Cₚ: parasitic capacitor

SW1: first switch

SW2: second switch

SW3: third switch

X₁: discharging end

X₂: charging end

VDD: input voltage

### DETAILED DESCRIPTION

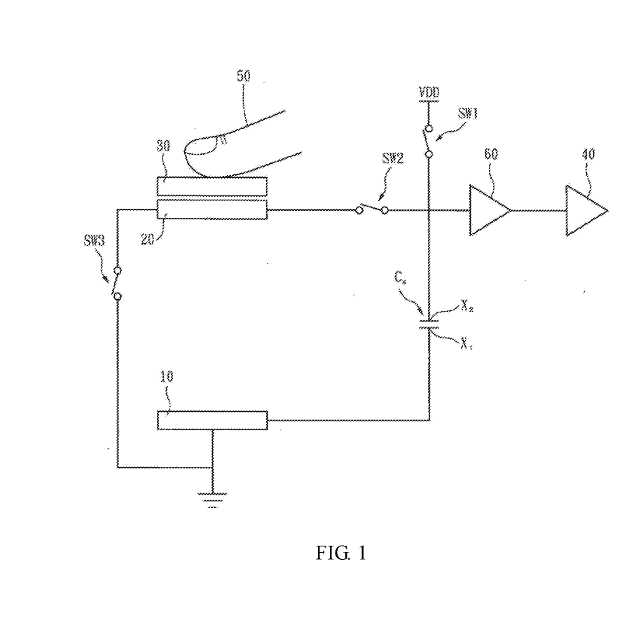

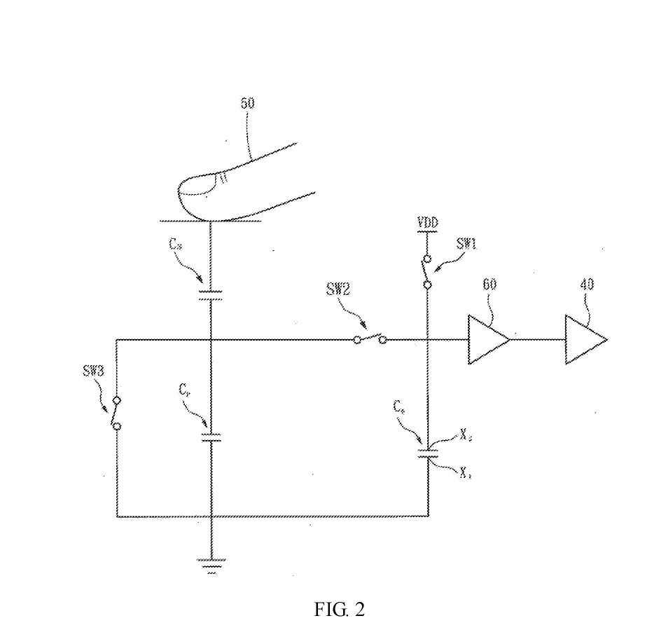

Detailed descriptions and technical content of the invention are now explained in combination with the accompanying drawings. Reference is made to FIGS. 1 and 2, which are a schematic circuit diagram according to a first embodiment of the present invention and an equivalent circuit diagram of FIG. 1, respectively, including a substrate 10, a conductive plate 20, a passivation layer 30, a charging capacitor C₀, a switch group, and an analog to digital (AD) converter 40. The conductive plate 20 is arranged on the substrate 10, and the passivation layer 30 is arranged on the conductive plate 20 for receiving a finger 50 to detect a fingerprint. In the invention, the term “receiving” means that the finger 50 is close to the passivation layer 30 with a distance therebetween (such as when a protective layer is additionally arranged on the passivation layer 30), or that the finger 50 is in partial or full contact with the passivation layer 30. At this time, a detecting capacitor Cₛ will be formed between the passivation layer 30 and the conductive plate 20, and the detecting capacitor Cₛ is functionally designed to detect and recognize lines patterns in the fingerprint. After the detecting capacitor Cₛ is formed, a parasitic capacitor Cₚ (or a stray capacitor) is formed between the conductive plate 20 and the substrate 10, and the parasitic capacitor Cₚ is an unintended capacitance form generated when circuit elements are overly close to one another.

The charging capacitor C₀ includes a discharging end X₁ and a charging end X₂. The discharging end X₁ is electrically connected to a low level voltage, and the discharging end X₁ is electrically connected to the substrate 10 in this embodiment, i.e. being connected to the ground, while the charging end X₂ is electrically connected to the conductive plate 20. The switch group includes a first switch SW1 and a second switch SW2, where the first switch SW1 has one end electrically connected to an input voltage VDD whose potential has to be higher than the low level voltage, and has another end electrically connected to the charging end X₂ of the charging capacitor C₀ to control the input voltage VDD to charge the charging capacitor C₀. That is, when the first switch SW1 is closed, the input voltage VDD will charge the charging capacitor C₀. The second switch SW2 has one end electrically connected to the conductive plate 20, and has another end electrically connected to the first switch SW1 and the charging end X₂ of the charging capacitor C₀. The AD converter 40 is electrically connected to the charging end X₂ of the charging capacitor C₀. In this way, the second switch SW2 will control the charging capacitor C₀ to perform charge sharing for multiple times, and the AD converter 40 outputs a fingerprint recognizing signal according to a residual voltage at the charging end X₂ after the charge sharing. Additionally in this embodiment, the fingerprint recognizing sensor with fast recognition further includes an amplifier 60 that is electrically connected to, and located before, the AD converter 40. The switch group further includes a third switch SW3 that is electrically connected to, and located between, the conductive plate 20 and ground, where the amplifier 60 may be a programmable designed gain amplifier.

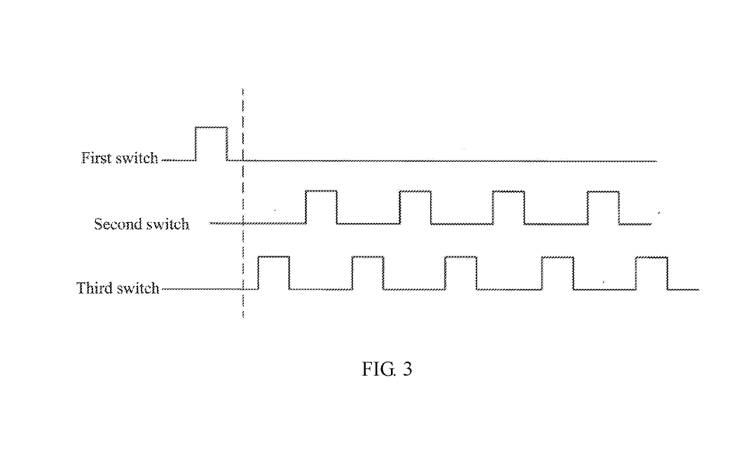

Continuing to FIG. 3, which is a control timing diagram according to the first embodiment of the present invention, operating steps of the first embodiment of the present invention are as the following:

Step 1: open the second switch SW2 and the third switch SW3 and close the first switch SW1, so that the input voltage VDD charges the charging capacitor C₀.

Step 2: open the first switch SW1 and the second switch SW2 and close the third switch SW3, allowing the detecting capacitor Cₛ and the parasitic capacitor Cₚ to be reset.

Step 3: open the first switch SW1, and alternately open and close the third switch SW3 and the second switch SW2 according to a time sequence so as to perform charge sharing. Repeat the process until a predefined number of times is reached, when all switching actions are stopped.

Step 4: the AD converter 40 outputs the fingerprint recognizing signal according to the residual voltage at the charging end X₂ after the charge sharing.

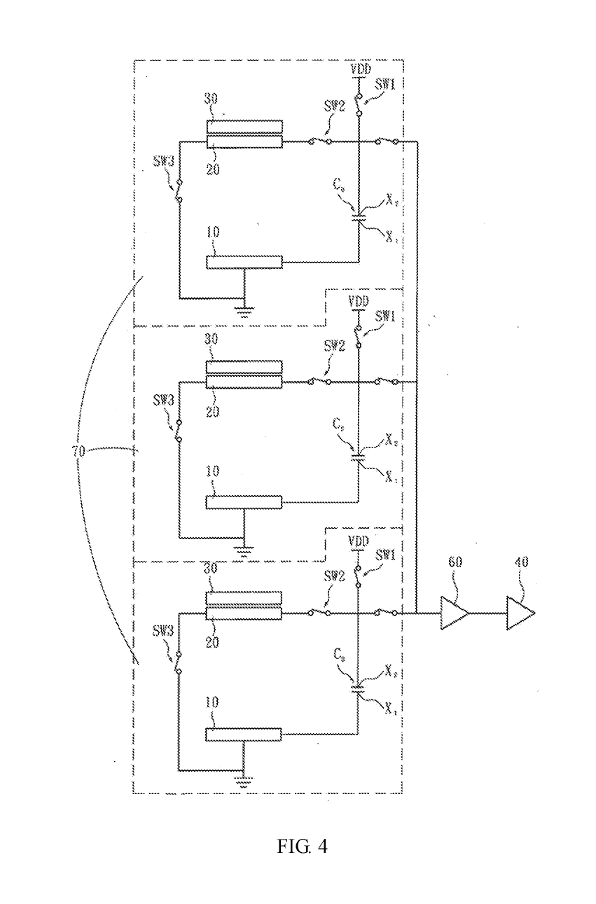

Reference is made to FIG. 4, which is a schematic circuit diagram according to a second embodiment of the present invention. A fingerprint recognizing sensor with fast recognition includes a substrate 10, a plurality of fingerprint recognition sensing units 70 arranged on the substrate 10, an amplifier 60, and an AD converter 40. The fingerprint recognition sensing units 70 are arranged on the substrate 10, each of which including a conductive plate 20 arranged on the substrate 10, a passivation layer 30 arranged on the conductive plate 20 for receiving a finger to detect a fingerprint, a charging capacitor C₀ and a switch group, where the charging capacitor C₀ includes a discharging end X₁ electrically connected to a low level voltage, and a charging end X₂ electrically connected to the conductive plate 20. In this embodiment, the low level voltage is the substrate 10.

The switch group includes a first switch SW1, a second switch SW2, and a third switch SW3. Two ends of the first switch SW1 are electrically connected to an input voltage VDD and the charging end X₂ of the charging capacitor C₀, respectively, and located between the input voltage VDD and the charging end X₂ of the charging capacitor C₀, so as to control the input voltage VDD to charge the charging capacitor C₀. The input voltage VDD has a potential higher than the low level voltage. Two ends of the second switch SW2 are electrically connected to the conductive plate 20 and the first switch SW1 as well as the charging end X₂ of the charging capacitor C₀, respectively. The third switch SW3 is electrically connected to, and located between, the conductive plate 20 and ground. The AD converter 40 is electrically connected to the charging end X₂ of the charging capacitor C₀ in each fingerprint recognition sensing unit 70. In this case, the second switch SW2 in the fingerprint recognition sensing unit 70 controls the charging capacitor CO to perform charge sharing for multiple times, and the AD converter 40 outputs a fingerprint recognizing signal according to a residual voltage at the charging end X₂ after the charge sharing. The second embodiment of this invention operates similarly to the first embodiment except for that, in the second embodiment, each of the fingerprint recognition sensing units 70 can perform the charge sharing simultaneously, firstly accumulate the residual voltage at the charging end X₂, and then make the same go through the AD converter 40 sequentially, so as to accomplish the fingerprint recognition.

In view of the above, the invention adopts the AD converter to output the fingerprint recognizing signal according to the residual voltage at the charging end after the charge sharing, where the input to, and output from, the AD converter are actual voltage values, which can be accomplished rapidly; instead, in a traditional C-V-T type capacitance sensor circuit, what is acquired by the comparator is the number of times of the reference capacitor charging circuit being closed and opened, rather than an actual voltage value, thus the speed is slow. Secondly, when multiple pixels (i.e. the fingerprint recognition sensing units) are arranged, the fingerprint recognition sensing units of the invention can simultaneously perform charge sharing, accumulate the residual voltage at the charging end and then go through the AD converter sequentially, which can be accomplished very rapidly as well; instead, in the traditional C-V-T type capacitance sensor circuit, each pixel has to wait for its previous pixel before the each pixel begins performing the switching operation, because simultaneous switching for the pixels are not allowed, thus the time for acquisition is slow. In addition, the output from the AD converter is an actual voltage value, which is convenient for subsequent signal processing; however, in the traditional C-V-T type capacitance sensor circuit, the output from the comparator is a value corresponding to the number of times of the switching operation. Moreover, during the charge sharing for multiple times, the residual voltage is the accumulation of signals after the charge sharing for multiple times, but the noise will not be accumulated accordingly, thus helping to improve the signal-to-noise ratio.

The present invention has been described in detail in the foregoing, and any or all equivalent alternatives, modifications or the like according to the application scope of the invention shall be deemed within the scope covered by this invention patent.

We claim:

1. A fingerprint recognizing sensor with fast recognition, comprising:
a substrate;
a conductive plate arranged on the substrate;
a passivation layer arranged on the conductive plate for receiving a finger to detect a fingerprint;
a charging capacitor, comprising a discharging end electrically connected to a low level voltage, and a charging end electrically connected to the conductive plate;
a switch group, comprising a first switch and a second switch, two ends of the first switch being electrically connected to an input voltage and the charging end of the charging capacitor, respectively, and located between the input voltage and the charging end of the charging capacitor, so as to control the input voltage to charge the charging capacitor; two ends of the second switch being electrically connected to the conductive plate and the first switch as well as the charging end of the charging capacitor, respectively; the input voltage being higher than the low level voltage; and
an analog to digital (AD) converter electrically connected to the charging end of the charging capacitor;
wherein after the first switch controls the charging capacitor to perform charging for a single time, the second switch controls the charging capacitor to perform charge sharing for multiple times, and the AD converter outputs a fingerprint recognizing signal according to a residual voltage at the charging end after the charge sharing.

2. The fingerprint recognizing sensor with fast recognition as claimed in claim 1, wherein the switch group further comprises a third switch electrically connected to, and located between, the conductive plate and a ground connection.

3. The fingerprint recognizing sensor with fast recognition as claimed in claim 1, further comprising an amplifier electrically connected to, and located before, the AD converter.

4. The fingerprint recognizing sensor with fast recognition as claimed in claim 3, wherein the amplifier is a programmable designed gain amplifier.

5. A fingerprint recognizing sensor with fast recognition, comprising:
a substrate;
a plurality of fingerprint recognition sensing units arranged on the substrate, each of the fingerprint recognition sensing units comprising:
a conductive plate arranged on the substrate;
a passivation layer arranged on the conductive plate for receiving a finger to detect a fingerprint;
a charging capacitor, comprising a discharging end electrically connected to a low level voltage, and a charging end electrically connected to the conductive plate;
a switch group, comprising a first switch and a second switch, two ends of the first switch being electrically connected to an input voltage and the charging end of the charging capacitor, respectively, and located between the input voltage and the charging end of the charging capacitor, to control the input voltage to charge the charging capacitor; two ends of the second switch being electrically connected to the conductive plate and the first switch as well as the charging end of the charging capacitor, respectively; the input voltage being higher than the low level voltage; and
an analog to digital (AD) converter electrically connected to the charging end of the charging capacitor in each of the fingerprint recognition sensing units;
wherein after the first switch in each of the fingerprint recognition sensing units controls the charging capacitor to perform charging for a single time, the second switch controls the charging capacitor to perform charge sharing for multiple times, and the AD converter outputs a fingerprint recognizing signal according to a residual voltage at the charging end after the charge sharing.

6. The fingerprint recognizing sensor with fast recognition as claimed in claim 5, wherein each of the fingerprint recognition sensing units further comprises a third switch electrically connected to, and located between, the conductive plate and a ground connection.

7. The fingerprint recognizing sensor with fast recognition as claimed in claim 5, further comprising an amplifier electrically connected to, and located before, the AD converter.

8. The fingerprint recognizing sensor with fast recognition as claimed in claim 7, wherein the amplifier is a programmable designed gain amplifier.
